(19) United States
(12) Patent Application Publication
(10) Pub. No.: US 2012/0270402 A1
(43) Pub. Date: Oct. 25, 2012

(54) METHOD OF MAKING AN ARRAY COLUMNAR HOLLOW SEMICONDUCTOR STRUCTURE

(75) Inventor: TAH-TE SHIH, TAIPEI (TW)

(73) Assignee: INOTERA MEMORIES, INC., TAOYUAN COUNTY (TW)

(21) Appl. No.: 13/112,002

(22) Filed: May 20, 2011

(30) Foreign Application Priority Data
Apr. 22, 2011 (TW) 100114115

(51) Int. Cl. H01L 21/311

(52) U.S. Cl. 438/694; 257/E21.249

(57) ABSTRACT

A method of making an array columnar hollow semiconductor structure includes: providing an oxide layer; placing a chromeless mask on the oxide layer, wherein the chromeless mask is a bank-shaped frame; forming a silicone nitride layer to cover the first partial top surface of the oxide layer and the whole outer surface of the bank-shaped frame; removing one part of the silicone nitride layer to expose a second partial top surface of the oxide layer and a top surface of the bank-shaped frame; removing the bank-shaped frame to expose a third partial top surface of the oxide layer; removing a first part of the oxide layer under the second partial top surface and a second portion of the oxide layer under the third partial top surface to form a plurality of columnar hollow bodies; and removing the other silicone nitride layer to completely expose the columnar hollow bodies.

### BACKGROUND OF THE INVENTION

1. Field of the Invention

The instant disclosure relates to a method of making an array columnar hollow semiconductor structure, and more particularly, to a method of making an array columnar hollow semiconductor structure applied to a trench capacitor.

2. Description of Related Art

Along with the miniaturization of various electronic products, the dynamic random access memory (DRAM) elements have to meet the demand of high integration and high density. A DRAM structure includes a capacitor for holding a charge and a transistor for accessing the charge held in the capacitor. DRAMs with trench capacitors or stacked capacitors are widely used in the industry so as to well utilize space of chips to effectively reduce memory cell size.

Typically, for trench-type DRAMs, trench capacitors are fabricated inside deep trenches that are formed in a semiconductor substrate by an etching process, followed by the manufacturing process of transistors. That is, the transistors such formed will be not affected by thermal budgets needed for forming the capacitors. However, the miniaturization of the unit trench type capacitor cell is limited by the difficulty of the deeper trench etching technology and the lack of relatively high-k capacitance dielectric material. For stack-type DRAMs, stacked capacitors are relatively easily formed. Generally, after transistors are formed, the stacked capacitors are formed thereon. There are various stack types, such as, plane, pillar, fin-type, and cylinder. The stack-type manufacturing process is more efficient and productive than the trench-type manufacturing process.

Also, there are various types of transistors, which may be categorized into two broad categories: planar transistor structures and vertical transistor structures, based upon the orientations of the channel regions relative to the primary surface of semiconductor substrate. Specifically, vertical transistor devices are devices in which the current flow between the source and drain regions of the devices is primarily substantially orthogonal to the primary surface of the semiconductor substrate, and planar transistor devices are devices in which the current flow between the source and drain regions is primarily parallel to the primary surface of the semiconductor substrate.

Along with the demand of miniaturization of DRAM elements, there is still a need for a novel DRAM structure and an array of the same with a smaller cell unit, higher integration or higher density.

### SUMMARY OF THE INVENTION

One particular aspect of the instant disclosure is to provide a method of making an array columnar hollow semiconductor structure that can be applied to the trench capacitor.

One of the embodiments of the instant disclosure provides a method of making an array columnar hollow semiconductor structure, comprising the steps of: providing an oxide layer, a first hard shielding layer, and a second hard shielding layer, wherein the first hard shielding layer is formed on the oxide layer, and the second hard shielding layer is formed on the first hard shielding layer; placing a chromeless mask formed by a chromeless phase-shift mask microlithography on the second hard shielding layer, wherein the chromeless mask is a first bank-shaped frame, and the first bank-shaped frame has a plurality of through openings; removing one part of the first hard shielding layer and one part of the second hard shielding layer that are not be shielded by the first bank-shaped frame for exposing a first partial top surface of the oxide layer, thus the other first hard shielding layer is formed as a second bank-shaped frame corresponding to the first bank-shaped frame; removing the first bank-shaped frame and the other second hard shielding layer to completely expose the second bank-shaped frame; forming a silicon nitride layer to cover the first partial top surface of the oxide layer and the whole outer surface of the second bank-shaped frame; removing one part of the silicon nitride layer to expose a second partial top surface of the oxide layer and a top surface of the second bank-shaped frame; removing the second bank-shaped frame to expose a third partial top surface of the oxide layer; removing a first part of the oxide layer under the second partial top surface of the oxide layer and a second part of the oxide layer under the third partial top surface of the oxide layer, thus the other oxide layer is formed as a plurality of columnar hollow bodies; and then removing the other silicon nitride layer to completely expose the columnar hollow bodies.

One of the embodiments of the instant disclosure provides a method of making an array columnar hollow semiconductor structure, comprising the steps of: providing an oxide layer; placing a chromeless mask formed by a chromeless phase-shift mask microlithography on the oxide layer, wherein the chromeless mask is a bank-shaped frame, and the bank-shaped frame has a plurality of through openings for exposing a first partial top surface of the oxide layer; forming a silicone nitride layer to cover the first partial top surface of the oxide layer and the whole outer surface of the bank-shaped frame; removing one part of the silicone nitride layer to expose a second partial top surface of the oxide layer and a top surface of the bank-shaped frame; removing the bank-shaped frame to expose a third partial top surface of the oxide layer; removing a first part of the oxide layer under the second partial top surface of the oxide layer and a second portion of the oxide layer under the third partial top surface of the oxide layer to form a plurality of columnar hollow bodies; and then removing the other silicone nitride layer to completely expose the columnar hollow bodies.

Therefore, the instant disclosure can provide a method of making an array columnar hollow semiconductor structure that can be applied to the trench capacitor due to the design of the chromeless mask formed by the chromeless phase-shift mask microlithography.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1 shows a flowchart of the method of making an array columnar hollow semiconductor structure according to the first embodiment of the instant disclosure;

FIGS. 1A to 1H are lateral, schematic views of an array columnar hollow semiconductor structure according to the first embodiment of the instant disclosure, at different stages of the manufacturing processes, respectively;

FIG. 2 shows a perspective, schematic view of the method of making an array columnar hollow semiconductor structure in the step S102 according to the first embodiment of the instant disclosure;

FIG. 3 shows a flowchart of the method of making an array columnar hollow semiconductor structure according to the second embodiment of the instant disclosure; and

FIGS. 3A to 3F are lateral, schematic views of an array columnar hollow semiconductor structure according to the second embodiment of the instant disclosure, at different stages of the manufacturing processes, respectively.

### DETAILED DESCRIPTION OF THE PREFERRED EMBODIMENTS

### First Embodiment

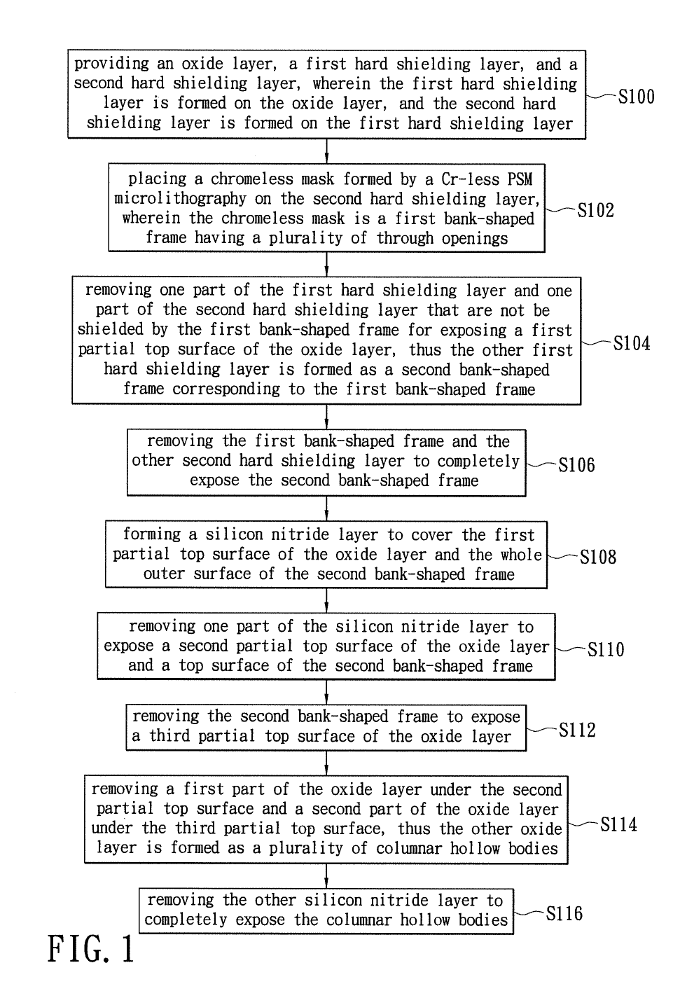

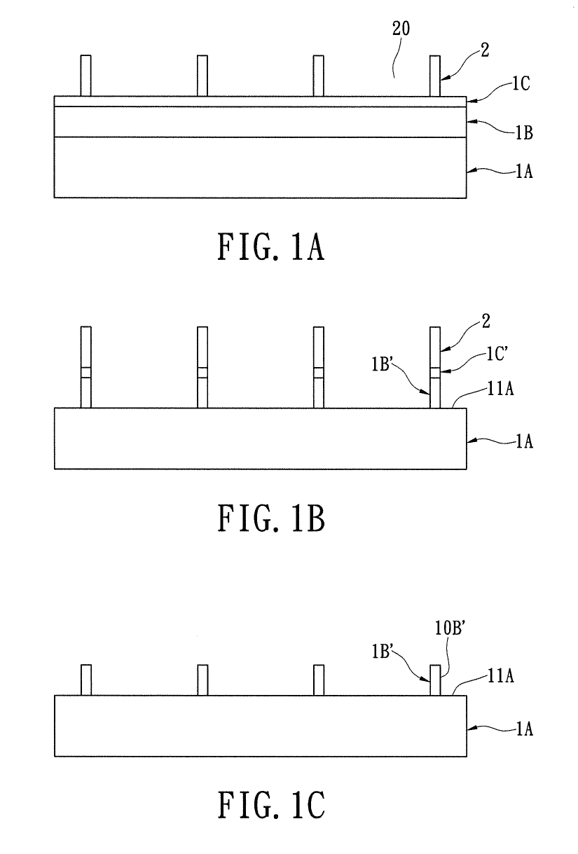

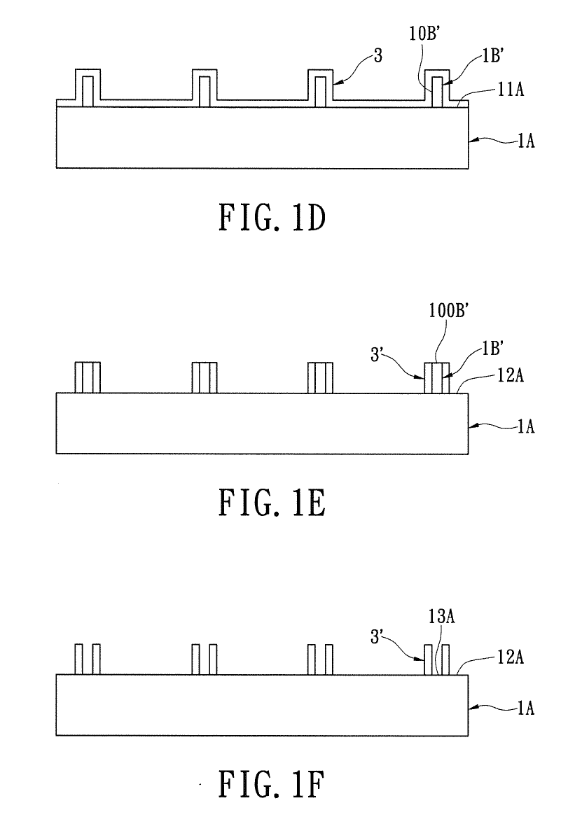

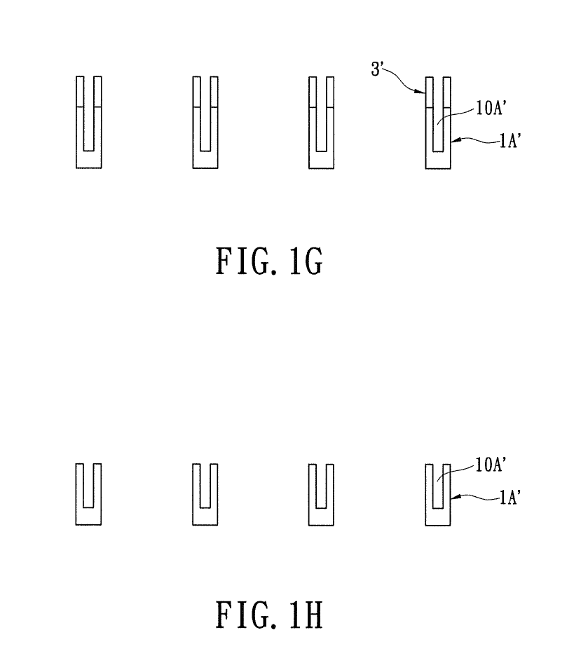

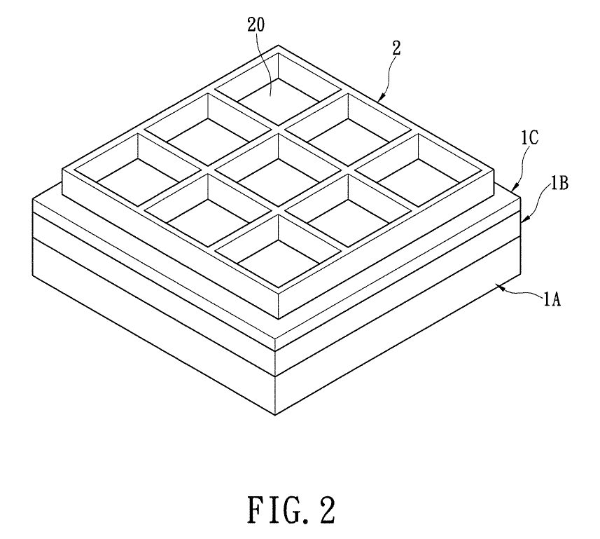

Referring to FIGS. 1, 1A-1H, and 2, where the first embodiment of the instant disclosure provides a method of making an array columnar hollow semiconductor structure, comprising the steps of (from the step S100 to the step S116):

The step S100 is that: referring to FIGS. 1, 1A, and 2 again, providing an oxide layer 1A, a first hard shielding layer 1B, and a second hard shielding layer 1C, wherein the first hard shielding layer 1B is formed on the oxide layer 1A, and the second hard shielding layer 1C is formed on the first hard shielding layer 1B. For example, the first hard shielding layer 1B may be an oxide shielding layer, and the second hard shielding layer 1C may be a carbon shielding layer.

The step S102 is that: referring to FIGS. 1, 1A, and 2 again, placing a chromeless mask formed by a chromeless phase-shift mask (Cr-less PSM) microlithography on the second hard shielding layer 1C, wherein the chromeless mask is a first bank-shaped frame 2, and the first bank-shaped frame 2 has a plurality of through openings 20. For example, the first bank-shaped frame 2 has a bank shape, thus the through openings 20 can be separated from each other by a predetermined distance and arranged as a matrix shape as shown in FIG. 2.

The step S104 is that: referring to FIGS. 1, 1A, and 1B again, removing (such as etching) one part of the first hard shielding layer 1B and one part of the second hard shielding layer 1C that are not be shielded by the first bank-shaped frame 2 for exposing a first partial top surface 11A of the oxide layer 1A, thus the other first hard shielding layer 1B is formed as a second bank-shaped frame 1B′ corresponding to the first bank-shaped frame 2. In other words, only the other first hard shielding layer 1B (the second bank-shaped frame 1B′) and the other second hard shielding layer 1C′ that are formed under the first bank-shaped frame 2 can be retained.

The step S106 is that: referring to FIGS. 1, 1B, and 1C again, removing the first bank-shaped frame 2 and the other second hard shielding layer C′ to completely expose the second bank-shaped frame 1B′. For example, the second bank-shaped frame 1B′ has a bank shape which is the same as the first bank-shaped frame 2, thus the through openings (not shown) of the second bank-shaped frame 1B′ can also be separated from each other by a predetermined distance and arranged as a matrix shape.

The step S108 is that: referring to FIGS. 1, 1C, and 1D again, forming a silicon nitride layer 3 to cover the first partial top surface 11A of the oxide layer 1A and the whole outer surface 10B′ of the second bank-shaped frame 1B′.

The step S110 is that: referring to FIGS. 1, 1D, and 1E again, removing (such as etching) one part of the silicon nitride layer 3 to expose a second partial top surface 12A of the oxide layer 1A and a top surface 100B′ of the second bank-shaped frame 1B′. In addition, one part of the silicon nitride layer 3 is removed to form a remainder silicon nitride layer 3′.

The step S112 is that: referring to FIGS. 1, 1E, and 1F again, removing the second bank-shaped frame 1B′ to expose a third partial top surface 13A of the oxide layer 1A.

The step S114 is that: referring to FIGS. 1, 1F, and 1G again, removing (such as etching) a first part of the oxide layer 1A under the second partial top surface 12A of the oxide layer 1A and a second part of the oxide layer 1A under the third partial top surface 13A of the oxide layer 1A, thus the other oxide layer 1A is formed as a plurality of columnar hollow bodies 1A′. For example, because the first part of the oxide layer 1A is formed under the second partial top surface 12A of the oxide layer 1A and the second part of the oxide layer 1A is formed under the third partial top surface 13A of the oxide layer 1A, the remainder oxide layer 1A becomes the columnar hollow bodies 1A′.

The step S116 is that: referring to FIGS. 1, 1G, and 1H again, removing the other silicon nitride layer 3′ to completely expose the columnar hollow bodies 1A′. For example, each columnar hollow body 1A′ has a micro columnar groove 10A′.

### Second Embodiment

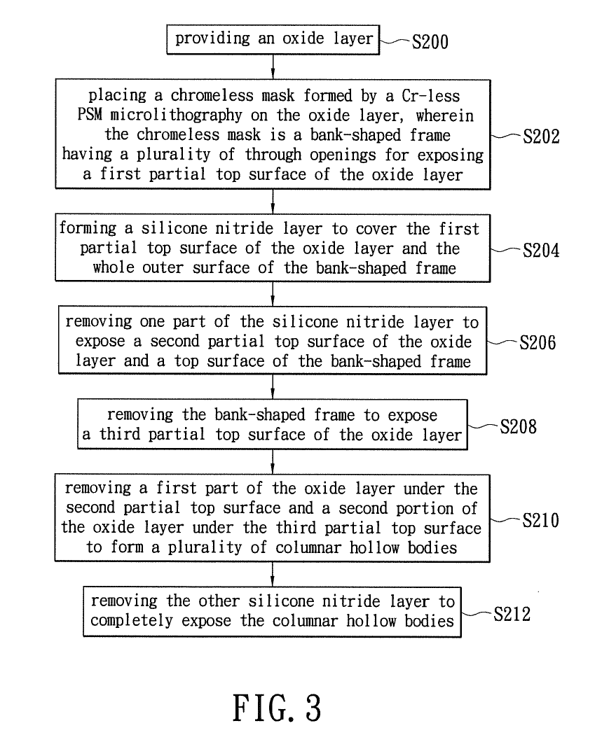

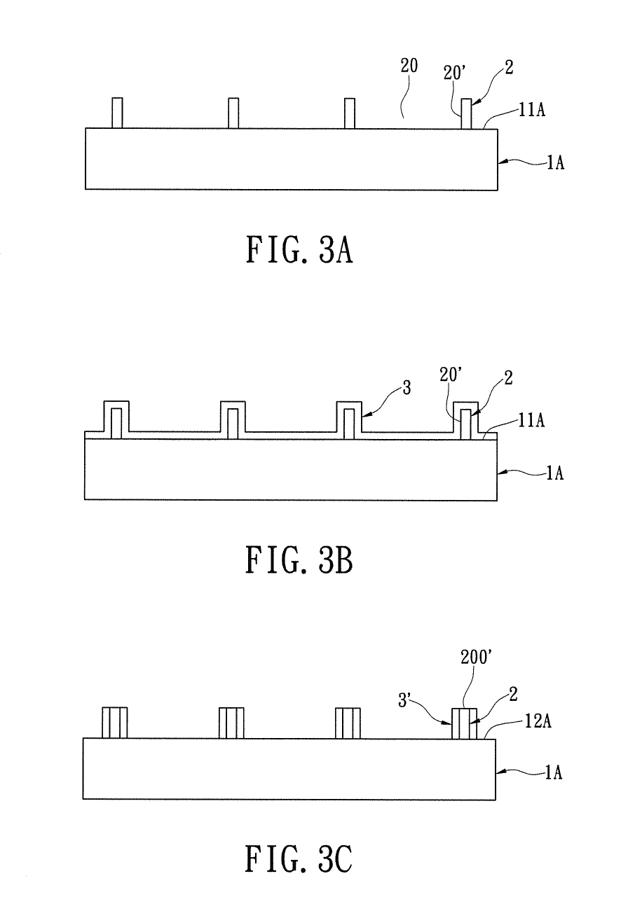

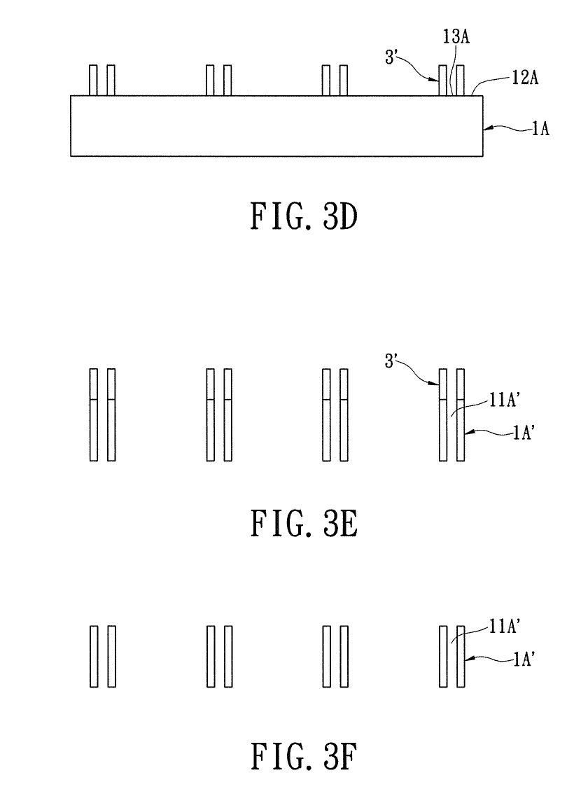

Referring to FIGS. 3, and 3A-3F, where the second embodiment of the instant disclosure provides a method of making an array columnar hollow semiconductor structure, comprising the steps of (from the step S200 to the step S212):

The step S200 is that: referring to FIGS. 3 and 3A again, providing an oxide layer 1A.

The step S202 is that: referring to FIGS. 3 and 3A again, placing a chromeless mask formed by a chromeless phase-shift mask microlithography on the oxide layer 1A, wherein the chromeless mask is a bank-shaped frame 2 which is the same as the first bank-shaped frame 2 of the first embodiment, and the bank-shaped frame 2 has a plurality of through openings 20 for exposing a first partial top surface 11A of the oxide layer 1A. For example, the bank-shaped frame 2 has a bank shape, thus the through openings 20 can be separated from each other by a predetermined distance and arranged as a matrix shape.

The step S204 is that: referring to FIGS. 3, 3A, and 3B again, forming a silicone nitride layer 3 to cover the first partial top surface 11A of the oxide layer 1A and the whole outer surface 20′ of the bank-shaped frame 2.

The step S206 is that: referring to FIGS. 3, 3B, and 3C again, removing (such as etching) one part of the silicone nitride layer 3 to expose a second partial top surface 12A of the oxide layer 1A and a top surface 200′ of the bank-shaped frame 20. In addition, one part of the silicon nitride layer 3 is removed to form a remainder silicon nitride layer 3′.

The step S208 is that: referring to FIGS. 3, 3C, and 3D again, removing the bank-shaped frame 20 to expose a third partial top surface 13A of the oxide layer 1A.

The step S210 is that: referring to FIGS. 3, 3D, and 3E again, removing (such as etching) a first part of the oxide layer 1A under the second partial top surface 12A of the oxide layer 1A and a second portion of the oxide layer 1A under the third partial top surface 13A of the oxide layer 1A to form a plurality of columnar hollow bodies 1A′. For example, because the first part of the oxide layer 1A is formed under the second partial top surface 12A of the oxide layer 1A and the second part of the oxide layer 1A is formed under the third partial top surface 13A of the oxide layer 1A, the remainder oxide layer 1A becomes the columnar hollow bodies 1A′.

The step S212 is that: referring to FIGS. 3, 3E, and 3F again, removing the other silicone nitride layer 3′ to completely expose the columnar hollow bodies 1A′. For example, each columnar hollow body 1A′ has a micro columnar through hole 11A′.

In conclusion, the instant disclosure can provide a method of making an array columnar hollow semiconductor structure that can be applied to the trench capacitor due to the design of the chromeless mask formed by the chromeless phase-shift mask microlithography.

The above-mentioned descriptions merely represent the preferred embodiments of the instant disclosure, without any intention or ability to limit the scope of the instant disclosure which is completely described only within the following claims. Various equivalent changes, alterations or modifications based on the claims of instant disclosure are all, consequently, viewed as being embraced by the scope of the instant disclosure.

What is claimed is:

1. A method of making an array columnar hollow semiconductor structure, comprising the steps of:
providing an oxide layer, a first hard shielding layer, and a second hard shielding layer, wherein the first hard shielding layer is formed on the oxide layer, and the second hard shielding layer is formed on the first hard shielding layer;
placing a chromeless mask formed by a chromeless phase-shift mask microlithography on the second hard shielding layer, wherein the chromeless mask is a first bank-shaped frame, and the first bank-shaped frame has a plurality of through openings;
removing one part of the first hard shielding layer and one part of the second hard shielding layer that are not be shielded by the first bank-shaped frame for exposing a first partial top surface of the oxide layer, thus the other first hard shielding layer is formed as a second bank-shaped frame corresponding to the first bank-shaped frame;
removing the first bank-shaped frame and the other second hard shielding layer to completely expose the second bank-shaped frame;
forming a silicon nitride layer to cover the first partial top surface of the oxide layer and the whole outer surface of the second bank-shaped frame;
removing one part of the silicon nitride layer to expose a second partial top surface of the oxide layer and a top surface of the second bank-shaped frame;
removing the second bank-shaped frame to expose a third partial top surface of the oxide layer;
removing a first part of the oxide layer under the second partial top surface of the oxide layer and a second part of the oxide layer under the third partial top surface of the oxide layer, thus the other oxide layer is formed as a plurality of columnar hollow bodies; and
removing the other silicon nitride layer to completely expose the columnar hollow bodies.

2. The method of claim 1, wherein the first hard shielding layer is an oxide shielding layer, and the second hard shielding layer is a carbon shielding layer.

3. The method of claim 1, wherein the removing steps are etching.

4. The method of claim 1, wherein the through openings are separated from each other by a predetermined distance and arranged as a matrix shape.

5. The method of claim 1, wherein each columnar hollow body has a micro columnar groove.

6. A method of making an array columnar hollow semiconductor structure, comprising the steps of:
providing an oxide layer;
placing a chromeless mask formed by a chromeless phase-shift mask microlithography on the oxide layer, wherein the chromeless mask is a bank-shaped frame, and the bank-shaped frame has a plurality of through openings for exposing a first partial top surface of the oxide layer;
forming a silicone nitride layer to cover the first partial top surface of the oxide layer and the whole outer surface of the bank-shaped frame;
removing one part of the silicone nitride layer to expose a second partial top surface of the oxide layer and a top surface of the bank-shaped frame;
removing the bank-shaped frame to expose a third partial top surface of the oxide layer;
removing a first part of the oxide layer under the second partial top surface of the oxide layer and a second portion of the oxide layer under the third partial top surface of the oxide layer to form a plurality of columnar hollow bodies; and
removing the other silicone nitride layer to completely expose the columnar hollow bodies.

7. The method of claim 6, wherein the removing steps are etching.

8. The method of claim 6, wherein the through openings are separated from each other by a predetermined distance and arranged as a matrix shape.

9. The method of claim 6, wherein each columnar hollow body has a micro columnar through hole.
